(19) United States
(12) Patent Application Publication
(10) Pub. No.: US 2026/0058442 A1
(43) Pub. Date: Feb. 26, 2026

(54) Quantum Cascade Lasers With Narrow Core Ridge Waveguide Design

(71) Applicant: IRGLARE, LLC, ORLANDO, FL (US)

(72) Inventor: Enrique Sanchez Cristobal, Orlando, FL (US)

(21) Appl. No.: 19/306,359

(22) Filed: Aug. 21, 2025

Related U.S. Application Data
(60) Provisional application No. 63/685,363, filed on Aug. 21, 2024.

(51) Int. Cl. H01S 5/34; H01S 5/10; H01S 5/22

(52) U.S. Cl. CPC H01S 5/3402; H01S 5/101; H01S 5/22

(57) ABSTRACT

A quantum cascade laser (QCL) includes a ridge waveguide formed on a semiconductor substrate. The ridge waveguide has a ridge with a ridge width and (a) a top cladding layer having a top cladding layer width, (b) a bottom cladding layer having a bottom cladding layer width, and (c) a QCL core layer having a QCL core layer width that is less than the top cladding layer width and the bottom cladding layer width. The QCL core layer is sandwiched between the top cladding layer and bottom cladding layer.

### CROSS-REFERENCE TO RELATED APPLICATION

This claims the benefit of priority to provisional Application No. 63/685,363, filed Aug. 21, 2024, which is incorporated by reference in its entirety.

### FIELD

This relates to the field of quantum cascade lasers and, more particularly to quantum cascade laser ridge waveguide designs.

### BACKGROUND

A quantum cascade laser (“QCL”) is a semiconductor laser that uses intersubband radiative electron transitions between quantized energy levels to generate photons of radiation. QCLs have a laser core or gain region composed of multiple semiconductor layers with alternating band gap values grown by molecular beam epitaxy or metal organic chemical vapor deposition techniques. QCLs offer high optical power, small size, and potentially low cost in the mid and long wave infrared spectrum.

An example of a conventional QCL generates light through optical transitions of electrons between energy levels in the conduction band of InGaAs/AllnAs quantum wells when an electric field is applied to form a staircase. By tailoring the dimensions of these quantum wells, the emission wavelength can be tuned from mid-wave infrared (MWIR) to long-wave infrared (LWIR) spectral regions. Typically, these semiconductor layers are epitaxially grown on an InP substrate using molecular beam epitaxy (MBE) or metalorganic vapor-phase epitaxy (MOVPE), allowing precise nanometric control of thickness.

Conventional QCLs utilize a double channel ridge waveguide geometry processed through photolithography, etching, and lift off techniques. These devices, which range from 3 mm to 10 mm in length, are formed by cleaving the semiconductor material along its crystallographic directions. The cleaved surfaces perpendicular to the ridge waveguide form the front and BACK facets of the QCL. Packaged QCLs can deliver several watts of optical power in both continuous wave and pulsed current operation, maintaining high beam quality, stable output power and wavelength. These characteristics make QCLs ideal for applications in spectroscopy, imaging, and defense.

Conventional QCLs suffer from modal losses due to the absorption of light, primarily caused by the interaction between the optical transverse magnetic (TM) mode and the surrounding metal film. This modal loss problem is particularly pronounced in wet-etched ridge waveguide QCLs due to the non-vertical sidewall profile. The semicircular profile of the laser core of a wet-etched QCL exacerbates this problem, as the electric field, oriented towards the growth direction of the laser core, interacts more strongly with the metal on the vertical sidewalls, leading to increased losses. Furthermore, a semicircular laser core shape fails to provide uniform current injection across all the QCL stages, especially in designs with a large number of stages in the active region.

Dry-etched ridge waveguides also experience losses, both from the interaction of the optical mode with the surrounding metal and from sidewall roughness. These losses become increasingly significant as the ridge width decreases, leading to higher optical losses and reduced overlap factor, diminishing the gain for the optical mode and reducing overall efficiency.

### BRIEF SUMMARY

These problems are solved by narrowing the quantum cascade laser core layer compared to the top and bottom cladding layers, creating a gap between the QCL core layer and electrically conductive layer. This increases the separation between the QCL core layer and electrically conductive layer, which increases the refractive index contrast and reduces interactions between the optical mode in QCL core layer and the electrically conductive layer.

An example of such a quantum cascade laser (QCL) includes a ridge waveguide formed on a semiconductor substrate. The ridge waveguide having a ridge with a ridge width and (a) a top cladding layer having a top cladding layer width, (b) a bottom cladding layer having a bottom cladding layer width, and (c) a QCL core layer having a QCL core layer width that is less than the top cladding layer width and the bottom cladding layer width.

The QCL core layer is sandwiched between the top cladding layer and bottom cladding layer.

The QCL may include one or more of the additional features described below.

The QCL may further include a dielectric material layer coating the top cladding layer, the bottom cladding layer, and the QCL core layer and an electrically conducting layer coating the dielectric material layer, where the ridge defines a gap between the electrically conductive layer and opposing sides of the QCL core layer.

The gap may reduce an optical interaction of the electrically conductive layer with an optical mode of the QCL core layer.

The dielectric material layer may be between the QCL core layer and the gap.

The gap may be defined by the electrically conductive layer, a bottom surface of the top cladding layer, a side surface of the QCL core layer, and a top surface of the bottom cladding layer.

The electrically conductive layer may form curved vertical sidewalls of the ridge.

The ridge waveguide may define a dry-etched channel, respectively, on opposed sides of the ridge.

The ridge waveguide may define a wet-etched channel, respectively, on opposed sides of the ridge.

The ridge waveguide may define a curved concave channel, respectively, on opposed sides of the ridge.

An example of a method of making a QCL includes forming a ridge waveguide structure having a ridge on a semiconductor substrate. The ridge waveguide structure includes (a) a top cladding layer having a top cladding layer width, (b) a bottom cladding layer having a bottom cladding layer width, and (c) a QCL core layer having a QCL core layer width. The QCL core layer is sandwiched between the top cladding layer and bottom cladding layer. The QCL core layer width of the formed ridge waveguide structure is reduced to be less than the top cladding layer width and the bottom cladding layer width. The ridge waveguide structure is coated with a dielectric material. The dielectric material is coated with an electrically conductive material while leaving a gap between the electrically conductive material and opposing sides of the QCL core layer.

The method may include one or more of the additional features described below.

Forming the ridge waveguide structure may include vertically etching the top cladding layer, the bottom cladding layer, and the QCL core layer and reducing the QCL core layer width may include laterally etching the QCL core layer.

Forming the ridge waveguide structure may include dry etching a channel, respectively, on opposed sides of the ridge and subsequently wet etching the QCL core layer to reduce the QCL core layer width.

Forming the ridge waveguide structure may include wet etching a curved concave channel, respectively, on opposed sides of the ridge and subsequently wet etching the QCL core layer to reduce the QCL core layer width.

The gap may reduce an optical interaction of the electrically conductive material with an optical mode of the QCL core layer.

The dielectric material may be between the QCL core layer and the gap.

The gap may be defined by the electrically conductive material, a bottom surface of the top cladding layer, a side surface of the QCL core layer, and a top surface of the bottom cladding layer.

The ridge waveguide structure may define a dry-etched channel, respectively, on opposed sides of the ridge.

The ridge waveguide structure may define a wet-etched channel, respectively, on opposed sides of the ridge.

The ridge waveguide structure may define a curved concave channel, respectively, on opposed sides of the ridge.

The electrically conductive layer may form curved vertical sidewalls of the ridge.

### BRIEF DESCRIPTION OF THE DRAWINGS

FIG. 1 is a schematic of an example of a QCL with a narrow core dry-etched ridge waveguide design.

FIG. 2 is an enlarged view of the central region of FIG. 1.

FIG. 3 is a schematic of an example of a QCL with a narrow core wet-etched ridge waveguide design.

FIG. 4 is an enlarged view of the central region of FIG. 3.

FIG. 5 is schematic of a QCL laser core layer.

FIG. 6A is a schematic of a wafer prior to fabricating the QCL device.

FIG. 6B is a schematic of the wafer of FIG. 6A with photoresist islands defined by optical lithography thereon.

FIG. 6C is a schematic of the wafer of FIG. 6B after having been vertically etched to define a ridge and channels.

FIG. 6D is a schematic of the wafer of FIG. 6C after having been laterally etched to reduce the width of the QCL core layer.

FIG. 7 is a graph a graph of the modal losses as a function of the QCL core layer width with and without the gap.

### DETAILED DESCRIPTION

This disclosure describes examples and features, but not all possible examples and features of the QCL and a method of making a QCL. Where a particular feature is disclosed in the context of a particular example, that feature can also be used, to the extent possible, in combination with and/or in the context of other features and examples. The QCL and method may be embodied in many different forms and should not be construed as limited to only the examples described here.

The problem with optical losses in QCLs with wet-etched and dry-etched ridge waveguides is solved by narrowing the width of the quantum cascade laser core layer relative to the top and bottom cladding layers. This introduces a gap between the sides of the QCL core and electrically conductive material layer, which enhances the refractive index contrast and pushes the optical mode into the quantum cascade laser core layer. This configuration reduces modal losses and allows for narrower quantum cascade laser core layer devices without significant efficiency penalties. This configuration can also reduce optical losses caused by scattering, particularly from dry-etched ridge waveguides with sidewall roughness.

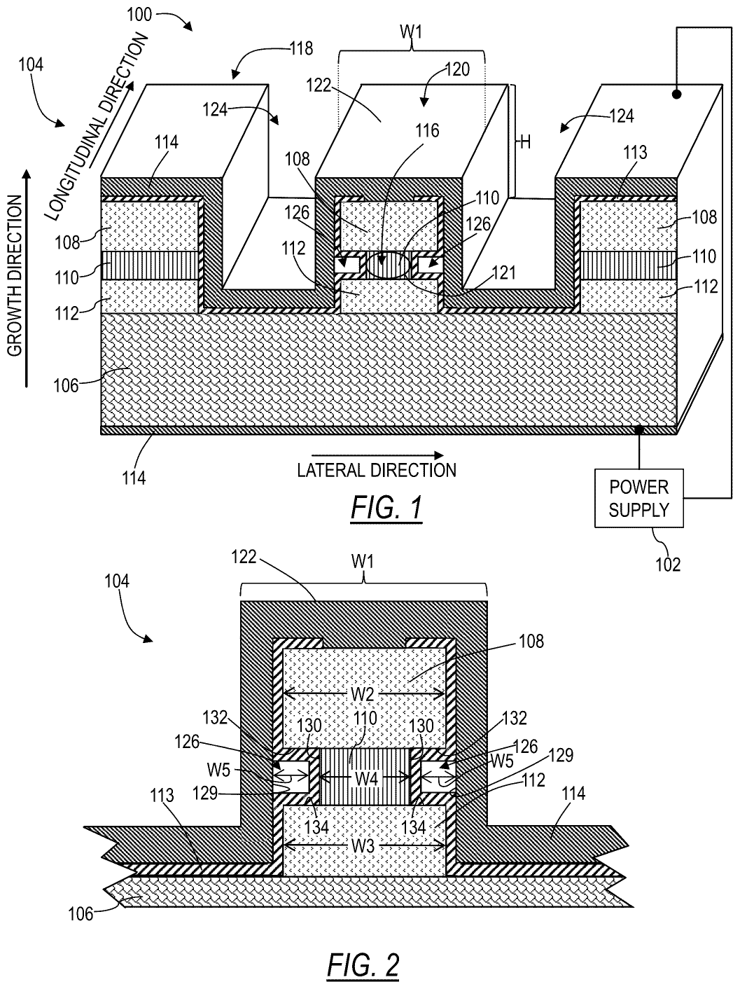

Referring to FIG. 1 a first example of such a QCL 100 includes a power supply 102 and a QCL device 104. The power supply 102 provides electric power to operate the QCL device 104. The QCL device 104 includes a substrate 106, a top cladding layer 108, a QCL core layer 110, a bottom cladding layer 112, a dielectric material layer 113, an electrically conductive layer 114, an output facet 116, and a back facet 118.

The power supply 102 may be a conventional QCL power supply. A typically QCL power supply, for example, operates at currents up to 20 A and voltages up to 25 V. Although the power supplied to the QCL device 104 is design and wavelength dependent, it typically supplies 2 A and 15 V to the QCL device 104.

The QCL device 100 may operate in either pulse or continuous wave (CW) mode. Pulse widths of the QCL device 104 may be <1 μs or 300 ns to 600 ns, for example.

The substrate 106 is made from one or more semiconducting materials. Examples of semiconducting materials suitable for the substrate 106 include, but are not limited to, InP, GaAs, InAs, Si, or the like. Other semiconducting materials used in a substrate layer of a QCL may be used.

The top cladding layer 108 and bottom cladding layer 112 are made from one or more semiconducting materials. Examples of suitable semiconducting materials for the cladding layers 108, 112 include, but are not limited to InP, InGaAs, and the like. Other semiconducting materials used in a cladding layer of a QCL may be used.

The top cladding layer 108, bottom cladding layer 112, and substrate 106 may be composed of the same semiconducting material or different semiconducting materials.

The dielectric material layer 113 may be composed of one or more dielectric materials such as silicon nitride, silicon dioxide, or the like, for example. Other dielectric materials used in a dielectric material layer of a QCL may be used.

The dielectric material layer 113 provides electrical insulation between the electrically conductive layer 114 and the top cladding layer 108, QCL core layer 110, and bottom cladding layer 112.

The electrically conductive layer 114 is made of one or more conducting materials, such as metals or the like, that allow the QCL device 104 to receive electrical power from the power supply 102.

The output facet 116 is the portion of QCL device 104 that outputs the radiation. The QCL device 104 in FIG. 1 is an edge emitting QCL because the output facet 116 is positioned on the edge of the QCL device 104. The output facet 116 emits radiation non-parallel, often substantially perpendicular to the growth direction.

Together, the top cladding layer 108, QCL core layer 110, and bottom cladding layer 112 cooperate to form an optical waveguide that guides radiation generated by the QCL core layer 110 along the waveguide.

The optical waveguide is a ridge waveguide 120 formed in the QCL device 104. The ridge waveguide 120 extends longitudinally from the back facet 118 to the output facet 116. The back facet 118 is opposite the output facet 116 and is designed to reflect radiation from the ridge waveguide 120 back into the ridge waveguide 120. The back facet 118 may be coated with a highly reflective coating capable of reflecting the radiation. Examples of highly reflective coatings include, but are not limited to metallic coatings such as gold and the like and/or multi-layer dielectric materials such as ZnSe, Y₂O₃, and Al₂O₃ and the like.

The ridge waveguide 120 is defined by a longitudinally extending ridge 122 having a ridge width W1 and a height H. The ridge 122 is bordered on either lateral side thereof by channels 124. The channels 124 extend down through the top cladding layers 108, QCL core layer 110, and bottom cladding layer 112.

In certain examples of the QCL device 104, the ridge width W1 is >100 μm, 4 μm-30 μm, or 5 μm-20 μm. In certain examples, the height H is 3 μm-15 μm. These dimensions can also vary outside the specified ranges for some applications.

The channels 124 may be left empty or, if desired, be filled with a semi-insulating material such as InP or the like. Filling the channels 124 with a semi-insulating material would provide a buried heterostructure (BH) configuration.

FIG. 2 is an enlarged view of the front face of FIG. 1, showing the central region of the QCL device 104 and ridge 122 in more detail. The top cladding layer 108 has a lateral top cladding layer width W2 and the bottom cladding layer has a lateral bottom cladding layer width W3. The top cladding layer width W2 and the bottom cladding layer width W3 are greater than a lateral QCL core layer width W4. Each of these widths is measured in the lateral direction from one lateral terminal side to the opposite lateral terminal side of the respective layer in the ridge 122.

Because the top cladding layer width W2 and the bottom cladding layer width W3 are greater than the QCL core layer width W4, the ridge 122 defines a pair of laterally opposed spaces 126 between an inner surface 129 of the electrically conductive layer 114 and opposing lateral sides 130 of the QCL core layer 110. At the spaces 126, the dielectric material layer 113 coats a bottom surface 132 of the top cladding layer 108, the lateral sides 130 of the QCL core layer 110, and a top surface 134 of the bottom cladding layer 112.

In certain examples, the top cladding layer width W2 and the bottom cladding layer width W3 are 5 μm-25 μm while the QCL core layer width W4 is less than W2 and W3 and is 5 μm-20 μm. In some examples, the top cladding layer width W2 and the bottom cladding layer width W3 are 300 nm-5 μm or 1.5 μm-2 μm wider than the QCL core layer width W4.

The spaces 126 appear as opposed air gaps between the dielectric material layer 113 and the electrically conductive layer 114. In certain examples, the gap has a lateral width W5 of 300 nm-5 μm or 500 nm-3 μm.

In a conventional dry-etched QCL ridge waveguide, these spaces are absent because the top cladding layer width W2, the bottom cladding layer width W3, and lateral quantum cascade core layer width W4 are substantially equal. The problem with this conventional construction is that the lateral sides of the conventional QCL core layer are only separated from the electrically conductive layer by the thickness of the dielectric material layer, which allows the optical mode in the QCL core layer to interact with the electrically conductive layer 114. In addition, dry-etched ridge waveguides can have sidewall roughness that increases optical scattering losses in the ridge waveguide, which can be mitigated by forming the spaces 126.

In a conventional wet-etched QCL ridge waveguide, these spaces are also absent and the same problem exists although W2, W3, and W4 are not substantially equal because the lateral sides 130 of the QCL core layer 110 are still only separated from the electrically conductive layer 114 by the thickness of the dielectric material layer 113.

In the QCL device 104 of FIG. 1, the ridge waveguide 120 is formed in the wafer by a dry-etching process that creates dry-etched channels 124 in which the electrically conductive layer 114 forms substantially vertical sidewalls on opposed sides of the ridge 122.

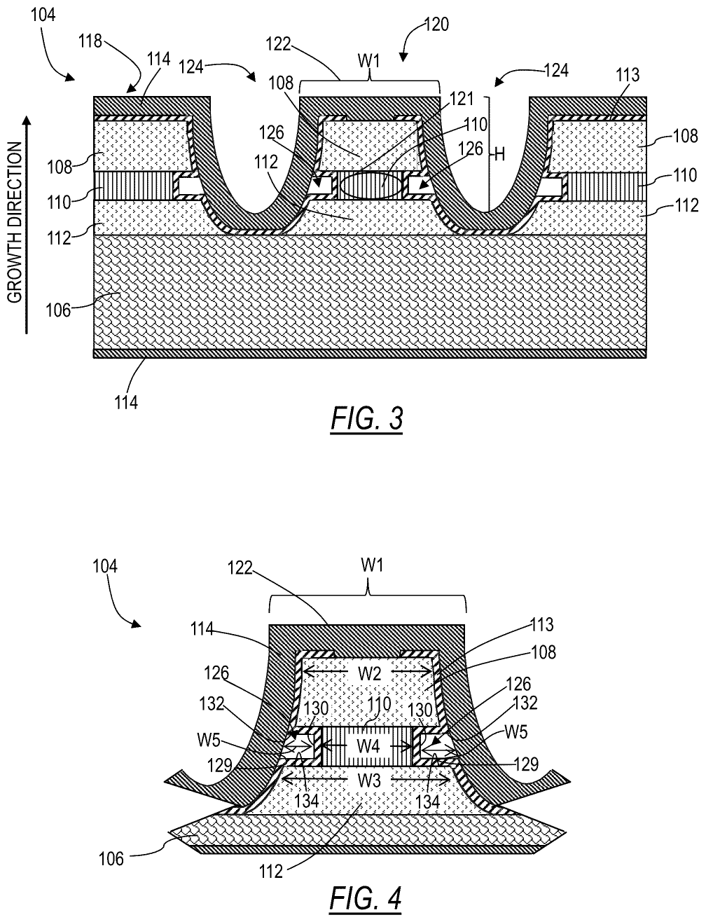

FIG. 3 is a schematic of another example of the QCL device 104 in which the ridge waveguide 120 is formed in the wafer by a wet-etching process that creates wet-etched concave channels 124 in which the electrically conductive layer 114 forms curved sidewalls on opposed sides of the ridge 122.

FIG. 4 is an enlarged view of the front face of the QCL device 104 of FIG. 3, showing the central region of the QCL device 104 and ridge 122 in more detail. The features are the same as in FIG. 2 except for the fact that wet etching makes the channels 124 concave and the opposed sides of the ridge 122 curved. Wet etching, likewise, makes the bottom cladding layer width W3 greater than the top cladding layer width W2 instead of leaving them substantially equal as they were with the dry-etched channels 124 of the QCL device 104 of FIG. 1.

The reference numerals used in the examples of FIG. 1-4 are the same because they refer to the same features in each example.

The QCL device 104 described here is much different than a conventional QCL because the ridge waveguide 120 is constructed to increase the separation between the electrically conductive layer 114 and the lateral sides 130 of the QCL core layer 110. This is achieved by constructing the gap 126 while fabricating the QCL device 104.

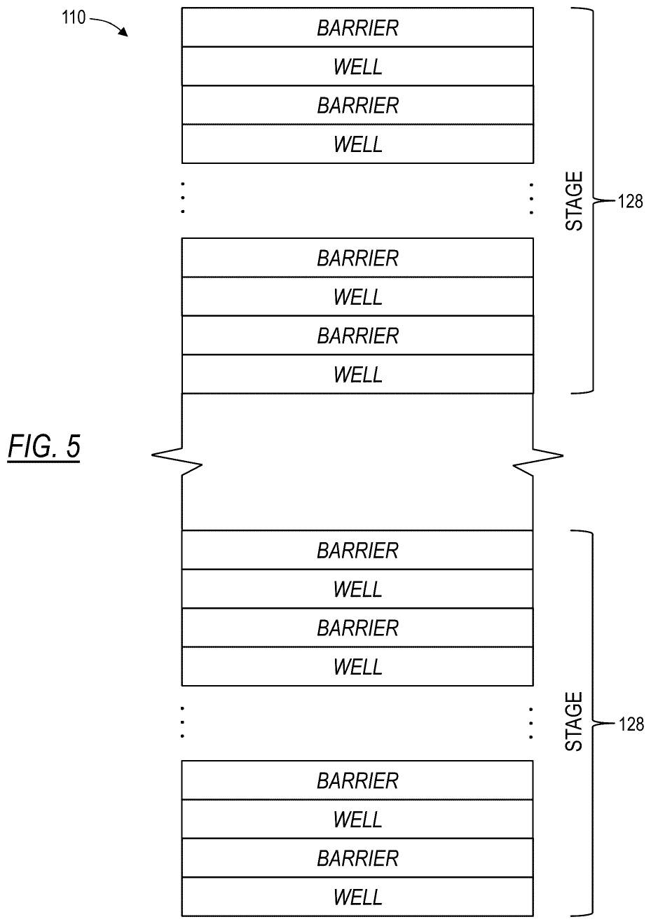

Referring to FIG. 5, details of the QCL core layer 110 are now described. The QCL core layer 110 is the laser gain region of the QCL, which generates photons via intersubband transitions. The QCL core layer 110 includes a plurality of stages 128 composed of optically interacting quantum wells and quantum barriers. When a voltage is applied across the QCL core layer 110, the stages 128 generate photons due to carrier excitation and relaxation between subbands. The number of stages 128 and thickness of stages 128 in the crystal growth direction can vary depending on the desired properties of the QCL device 104. The QCL core layer 110 is grown in the growth direction shown in FIGS. 1 and 3 using a semiconductor growth technique such as molecular beam epitaxy, metal organic chemical vapor deposition, and/or the like.

The quantum wells may be made of one or more semiconducting materials. Examples of semiconducting materials suitable for the quantum wells include, but are not limited to, InGaAs, GaAs, InAs, and the like.

The quantum barriers may be made of one or more semiconducting materials. Examples of semiconducting materials suitable for the quantum barriers include, but are not limited to, AlInAs, AlAsSb, AISb, and the like.

A typical example of a QCL core layer 110 has 30-50 stages 128 in which each stage 128 has a thickness of approximately 30 to 60 nm.

In other examples of the QCL device 104, the ridge waveguide 120 may have more than one QCL core layer 110 in a stack in which each respective QCL core layer 110 is separated by a InP or InGaAs layer.

An example of a method of making the QCL device 104 of FIGS. 1-4 will now be described. The QCL device 104 may be made using semiconductor device fabrication techniques. The method is performed on a wafer having the top cladding layer 108, QCL core layer 110, and bottom cladding layer 112 pre-grown in the growth direction on the substrate 106.

The method includes forming a ridge waveguide structure having a ridge 122 on the semiconductor substrate 106. The term ridge waveguide structure refers to the ridge waveguide 120 without the dielectric material layer 113 and electrically conductive layer 114. The ridge waveguide structure includes the top cladding layer 108 having the top cladding layer width W2, (b) the bottom cladding layer 112 having the bottom cladding layer width W3, and (c) a QCL core layer 110 having the QCL core layer width W4 and being sandwiched between the top cladding layer 108 and bottom cladding layer 112.

The forming step involves etching the channels 124 into the wafer using a semiconductor etching technique. Dry etching produces substantially vertical sidewalls in the channels 124 as shown in FIGS. 1 and 2. Wet etching produces curved sidewalls and concave channels as shown in FIGS. 3 and 4.

The method further includes reducing the QCL core layer width W3 of the formed ridge waveguide structure to be less than the top cladding layer width W2 and the bottom cladding layer width W3. This is achieved by laterally etching the QCL core layer 110 using an etchant that selectively etches the QCL core layer 110 and substantially does not etch the top cladding layer 108 or bottom cladding layer 112. This is achieved using a wet etchant capable of selectively etching the QCL core layer 110 material. A suitable example of such an etchant is 1:1:38 solution of H3PO4:H2O2:H2O. This step reduces the QCL core layer width W4 to be less than the top cladding layer width W2 and the bottom cladding layer width W3. This step advantageously forms the basis of the gap 126 of the finished QCL device 104 of FIGS. 1-4.

Once the ridge waveguide structure is formed, the ridge waveguide structure is coated with the dielectric material forming the dielectric material layer 113 in such a way that the dielectric material layer 113 coats the bottom surfaces 132, top surfaces 134, and lateral sides 130 leaving a gap between the bottom surfaces 132 and top surfaces 134, which will become the gap 126 on each side of the ridge waveguide 120. This may be achieved by depositing the dielectric material of the dielectric material layer 113 using a conformal deposition process such as plasma enhanced chemical vapor deposition (PECVD) or the like.

The dielectric material layer 113 is subsequently coated with the electrically conductive layer 114 using an ordinary vapor deposition technique, in which case the electrically conductive material covers the gap between the bottom surface 132 and the top surface 134, thereby covering the opposed lateral ends of the gap 126 as shown in FIGS. 1-4.

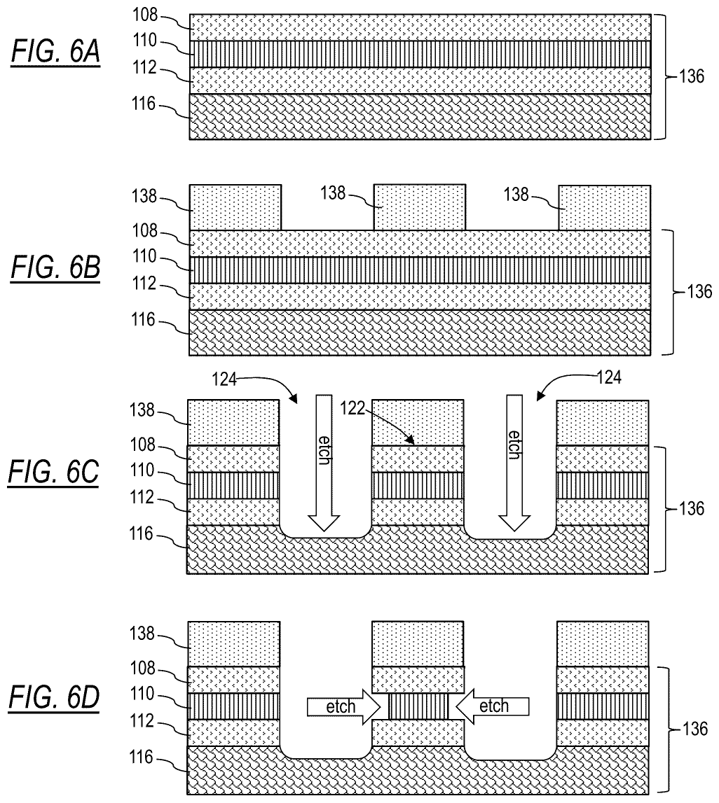

A particular example of this method will now be described with reference to FIGS. 6A-D.

In FIG. 6A, the method begins with a pre-prepared wafer 136 composed of the top cladding layer 108, QCL core layer 110, bottom cladding layer 112, and substrate 106.

The method continues in FIG. 6B with an optical lithography step in which photoresist 138 is applied to the wafer 136 and optical lithography is used to define areas of the wafer 136 to be etched. The photoresist 138 protects the areas it covers so these areas remain intact during etching.

The method continues in FIG. 6C with an etching step in which the wafer 136 is vertically etched to define the ridge 122 and the channels 124. This etching step may be achieved using conventional semiconductor dry-etching and/or wet-etching techniques and suitable etchants for the materials selected for each layer.

The method continues in FIG. 6D with a wet etching step in which the wafer 136 is laterally wet-etched in such a way that the QCL core layer 110 is selectively etched, causing it to narrow relative to the top cladding layer 108 and bottom cladding layer 112.

The lateral etching distance may be controlled by knowing the etching rate of the etchant on the material forming the QCL core layer 110 and watching the etching process through a microscope in real time and stopping etching at the desire distance.

The etched wafer 136 of FIG. 6D is further processed by coating the ridge 122 with the dielectric material layer 113 in such a way that the dielectric material layer 113 coats the lateral sides 130 of the QCL core layer 110, bottom surface 132 of the top cladding layer 108, and top surface 134 of the bottom cladding layer 112 as shown in FIGS. 1-4.

The electrically conductive layer 114 is subsequently applied to the dielectric material layer 113.

A QCL device 104 with ridge waveguides 120 having the gap 126 provides advantages for both wet-etched and dry-etched waveguides. In conventional wet-etched ridge waveguides, the concave semicircular profile of the core causes the electric field, due to its TM polarization, to interact more strongly with the electrically conductive material on the sidewalls. The gap design eliminates this semicircular profile of the QCL core layer 110 and reduces the optical mode 121 and electrically conductive layer 114 interaction. Additionally, having a QCL core layer 110 with substantially vertical sides promotes more uniform current injection across the stages of the QCL device 104.

Designing a QCL device 104 with ridge waveguides 120 having the gap 126 also overcomes a problem with conventional ridge waveguides, namely, when the QCL core layer width decreases it increases the optical interactions between the QCL core layer and the electrically conductive layer. Introducing the gap 126 allows the QCL core layer width W4 to be reduced without increasing the optical interactions between the QCL core layer 110 and the electrically conductive layer 114. Introducing the gap 126 also reduces losses in curved waveguides, such as in ring resonators and arrays. The optical mode 121 in curved waveguides interacts strongly with the electrically conductive layer 114 because the optical mode 121 gets pushed away from the direction of curvature. For example, in a ring resonator, the optical mode 121 is pushed towards the outer edge of the waveguide. Introducing the gap 126 could be used in ring waveguides with reduced radii by reducing losses from interactions between the optical mode 121 and electrically conductive layers 114.

The improved QCL device 104 design described here can be applied to various types of QCLs, including distributed Bragg reflector (DBR) QCLs, distributed feedback (DFB) QCLs, ring resonators, and array configurations. Furthermore, this design allows for the production of devices with narrower QCL core layer widths W4 without incurring significant losses, thus offering improved performance and versatility in QCL applications requiring high beam quality and efficiency.

### EXAMPLES

This section provides examples of a wet etching process, a dry etching process, and modal loss simulations. These examples are provided to illustrate features of the method and QCL device.

### Example 1: Modal Loss Computations

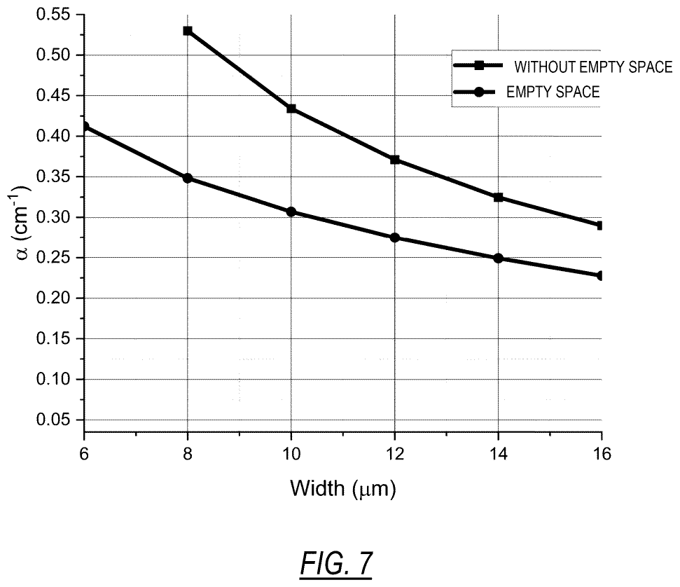

Modal losses as a function of the QCL core layer width were computed for ridge waveguides with the gap and without the gap. FIG. 7 is a graph showing the modal loss as a function of the QCL core layer width for a QCL without the gap and a QCL with the gap. For these simulations, a vertical sidewall was assumed, the gap width was 2 μm on each side, the thickness of the dielectric material layer (Si₃N₄) was 270 nm, and the wavelength was 4.0 μm. The data show that the ridge waveguide with gap design exhibits significantly lower modal losses compared to the ridge waveguide without the gap. Specifically, for ridge widths of 16 μm, the losses are 21.5% lower with the gap. For ridge widths of 8 μm, they are 34.3% lower. These simulations highlight the utility of the new ridge waveguide design to enhance the efficiency of QCLs.

### Example 2: Forming Ridge Waveguides by Dry Etching

A dry-etched ridge waveguide was formed by hard mask deposition (dielectric: SiO2), spin coating of photoresist to define the waveguide pattern using optical UV lithography, dry etching of SiO2 to transfer the waveguide pattern to the hard mask layer, and dry etching of the wafer to transfer the waveguide to the QCL stack. The gap was defined after completing dry etching the QCL stack. The wafer was cleaned with oxygen plasma followed by a treatment on CHF3 plasma for 2 min, then cleaned in oxygen plasma. The wafer was then submerged in H3PO4:H2O2:H2O (1:1:38) solution which laterally etched the core at a rate ˜100 nm/min. The lateral width of the gap was monitored with optical microscope.

### Example 3: Forming Ridge Waveguides by Wet Etching

A wet-etched waveguide was formed by spin coating photoresist on the wafer to define the waveguide pattern using optical UV lithography, wet etching the wafer in a standard HBr based solution to transfer the waveguide to the QCL stack. The gap was defined by submerging the wet-etched wafer in H₃PO₄:H₂O_{2:}H₂O (1:1:38) solution which laterally etched the core at a rate ˜100 nm/min. The lateral width of the gap was monitored with an optical microscope.

A person having ordinary skill in the art will understand that the QCL, the method, and their features may be modified in many different ways without departing from the scope of what is claimed. The scope of the claims is not limited to only the particular features and examples described above.

1. A quantum cascade laser (QCL) comprising:
a ridge waveguide formed on a semiconductor substrate, the ridge waveguide having a ridge with a ridge width and:
(a) a top cladding layer having a top cladding layer width,
(b) a bottom cladding layer having a bottom cladding layer width, and
(c) a QCL core layer having a QCL core layer width that is less than the top cladding layer width and the bottom cladding layer width, the QCL core layer being sandwiched between the top cladding layer and bottom cladding layer.

2. The QCL of claim 1, further comprising a dielectric material layer coating the top cladding layer, the bottom cladding layer, and the QCL core layer; and
an electrically conducting layer coating the dielectric material layer;
wherein the ridge defines a gap between the electrically conductive layer and opposing sides of the QCL core layer.

3. The QCL of claim 2, wherein the gap reduces an optical interaction of the electrically conductive layer with an optical mode of the QCL core layer.

4. The QCL of claim 2, wherein the dielectric material layer is between the QCL core layer and the gap.

5. The QCL of claim 2, wherein the gap is defined by the electrically conductive layer, a bottom surface of the top cladding layer, a side surface of the QCL core layer, and a top surface of the bottom cladding layer.

6. The QCL of claim 2, wherein the electrically conductive layer forms curved vertical sidewalls of the ridge.

7. The QCL of claim 1, wherein the ridge waveguide defines a dry-etched channel, respectively, on opposed sides of the ridge.

8. The QCL of claim 1, wherein the ridge waveguide defines a wet-etched channel, respectively, on opposed sides of the ridge.

9. The QCL of claim 1, wherein the ridge waveguide defines a curved concave channel, respectively, on opposed sides of the ridge.

10. A method of making a quantum cascade laser (QCL), the method comprising:
forming a ridge waveguide structure having a ridge on a semiconductor substrate, the ridge waveguide structure including (a) a top cladding layer having a top cladding layer width, (b) a bottom cladding layer having a bottom cladding layer width, and (c) a QCL core layer having a QCL core layer width and being sandwiched between the top cladding layer and bottom cladding layer;
reducing the QCL core layer width of the formed ridge waveguide structure to be less than the top cladding layer width and the bottom cladding layer width;
coating the ridge waveguide structure with a dielectric material; and
coating the dielectric material with an electrically conductive material while leaving a gap between the electrically conductive material and opposing sides of the QCL core layer.

11. The method of claim 10, wherein forming the ridge waveguide structure includes vertically etching the top cladding layer, the bottom cladding layer, and the QCL core layer; and,
reducing the QCL core layer width includes laterally etching the QCL core layer.

12. The method of claim 10, wherein forming the ridge waveguide structure includes dry etching a channel, respectively, on opposed sides of the ridge and subsequently wet etching the QCL core layer to reduce the QCL core layer width.

13. The method of claim 10, wherein forming the ridge waveguide structure includes wet etching a curved concave channel, respectively, on opposed sides of the ridge and subsequently wet etching the QCL core layer to reduce the QCL core layer width.

14. The method of claim 10, wherein the gap reduces an optical interaction of the electrically conductive material with an optical mode of the QCL core layer.

15. The method of claim 10, wherein the dielectric material is between the QCL core layer and the gap.

16. The method of claim 10, wherein the gap is defined by the electrically conductive material, a bottom surface of the top cladding layer, a side surface of the QCL core layer, and a top surface of the bottom cladding layer.

17. The method of claim 10, wherein the ridge waveguide structure defines a dry-etched channel, respectively, on opposed sides of the ridge.

18. The method of claim 10, wherein the ridge waveguide structure defines a wet-etched channel, respectively, on opposed sides of the ridge.

19. The method of claim 10, wherein the ridge waveguide structure defines a curved concave channel, respectively, on opposed sides of the ridge.

20. The method of claim 10, wherein the electrically conductive layer forms curved vertical sidewalls of the ridge.
